(19) United States
(12) Patent Application Publication
(10) Pub. No.: US 2024/0030323 A1
(43) Pub. Date: Jan. 25, 2024

(54) Power Semiconductor Device and Method of Producing a Power Semiconductor Device

(71) Applicant: Infineon Technologies AG, Neubiberg (DE)

(72) Inventors: Alexander Philippou, München (DE); Hans-Jürgen Thees, Dresden (DE); Thorsten Arnold, Jesenwang (DE)

(21) Appl. No.: 18/352,667

(22) Filed: Jul. 14, 2023

(30) Foreign Application Priority Data
Jul. 25, 2022 (DE) 102022118545.1

(51) Int. Cl. H01L 29/739; H01L 29/66; H01L 29/423

(52) U.S. Cl. CPC H01L 29/7397; H01L 29/66333; H01L 29/4236

(57) ABSTRACT

A power semiconductor device and a method of producing a power semiconductor device are presented. The power semiconductor device is, for example, embodied as an IGBT and includes a deep cross trench which extends below trenches that include, e.g., control and source trench electrodes.

### TECHNICAL FIELD

This specification refers to embodiments of a power semiconductor device and to embodiments of a method of producing a power semiconductor device. In particular, this specification refers to a power semiconductor device that is for example embodied as an IGBT and includes a deep cross trench which extends below trenches that include, e.g., control and source trench electrodes, and to embodiments of a corresponding production method.

### BACKGROUND

Many functions of modern devices in automotive, consumer and industrial applications, such as converting electrical energy and driving an electric motor or an electric machine, rely on power semiconductor switches. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device.

Further, in case of a controllable power semiconductor device, e.g., a transistor, the load current path may be controlled by means of an insulated control electrode, commonly referred to as gate electrode. For example, upon receiving a corresponding control signal from, e.g., a driver unit, the control electrode may set the power semiconductor device in one of a forward conducting state and a blocking state.

For example, the control electrodes may be arranged in trenches extending into the semiconductor body, e.g., in stripe trenches that extend through the active region of the device's chip. Some of the stripe trenches may house other types of electrodes, such as source trench electrodes and/or floating trench electrodes and/or further control trench electrodes. The regions of the semiconductor body laterally confined by such trenches are typically referred to as mesas. Some of the mesas may be active mesas that carry the load current and that may be controlled based on an adjacent control trench electrode. Other mesas may not be connected to the load terminal (“dummy mesas”) and yet other mesas may be connected to the load terminal but used for control of the plasma rather than for switching. It is conceivable that various trench-mesa-patterns may be implemented.

One of the challenges associated with such structures, in particular in case of higher carrier confinements, is to maintain controllability of the device, e.g., to keep the rate of change of the forward voltage (dV/dt or, respectively, dU/dt, or dI/dt) during switching process within certain limits.

### SUMMARY

According to an embodiment, a power semiconductor device comprises: a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. The deep cross trench includes a deep cross trench electrode and a deep cross trench insulator electrically insulating the deep cross trench electrode from the semiconductor body. Each of said control trenches includes a control trench insulator electrically insulating the control trench electrode from the semiconductor body. The thickness of the deep cross trench insulator amounts to at least 150% of the average thickness of the control trench insulators.

According to a further embodiment, a power semiconductor device comprises a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. At least an upmost portion of the deep cross trench is made of an insulating material, said upmost portion vertically overlapping with at least the average upmost quarter of the first trenches.

According to a further embodiment, a method of producing a power semiconductor device comprises forming the following components: a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. The method is carried out such that: The deep cross trench includes a deep cross trench electrode and a deep cross trench insulator electrically insulating the deep cross trench electrode from the semiconductor body; each of said control trenches includes a control trench insulator electrically insulating the control trench electrode from the semiconductor body; and such that the thickness of the deep cross trench insulator amounts to at least 150% of the average thickness of the control trench insulators.

According to a further embodiment, a method of producing a power semiconductor device comprises forming the following components: a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. The method is carried out such that at least an upmost portion of the deep cross trench is made of an insulating material, said upmost portion vertically overlapping with at least the average upmost quarter of the first trenches.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a horizontal projection of a power semiconductor device in accordance with one or more embodiments;

FIG. 2 schematically and exemplarily illustrates a section of a vertical cross-section of an active region of a power semiconductor device in accordance with one or more embodiments;

FIG. 3 schematically and exemplarily illustrates a section of a horizontal projection of a power semiconductor device in accordance with one or more embodiments;

FIG. 4 schematically and exemplarily illustrates a section of a vertical cross-section of an active region of a power semiconductor device in accordance with one or more embodiments;

FIG. 5 schematically and exemplarily illustrates a respective perspective view on a section of a vertical cross-section of an active region of a power semiconductor device in accordance with some embodiments;

FIG. 6 schematically and exemplarily illustrates a respective perspective view on a section of a vertical cross-section of an active region of a power semiconductor device in accordance with some embodiments;

FIG. 7 schematically and exemplarily illustrates a respective perspective view on a section of a vertical cross-section of an active region of a power semiconductor device in accordance with some embodiments;

FIG. 8 schematically and exemplarily illustrates a section of a horizontal projection of a power semiconductor device in accordance with one or more embodiments; and

FIGS. 9-1 to 9-14 schematically and exemplarily illustrate a method of producing a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged with an active region of the power semiconductor device.

The term “blocking state” of the power semiconductor device may refer to conditions, when the semiconductor device is in a state configured for blocking a current flow through the semiconductor device, while an external voltage is applied. More particularly, the semiconductor device may be configured for blocking a forward current through the semiconductor device while a forward voltage bias is applied. In comparison, the semiconductor may be configured for conducting a forward current in a “conducting state” of the semiconductor device, when a forward voltage bias is applied. A transition between the blocking state and the conducting state may be controlled by a control electrode or, more particularly, a potential of the control electrode.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

The present specification in particular relates to a power semiconductor device embodied as an IGBT or as an MOSFET, i.e., a bipolar or unipolar power semiconductor transistor or a derivate thereof that is controlled based on insulated gate electrodes.

For example, the power semiconductor device described below may be implemented on a single semiconductor chip and can be configured to be employed as a power component in a low-, medium- and/or high voltage application.

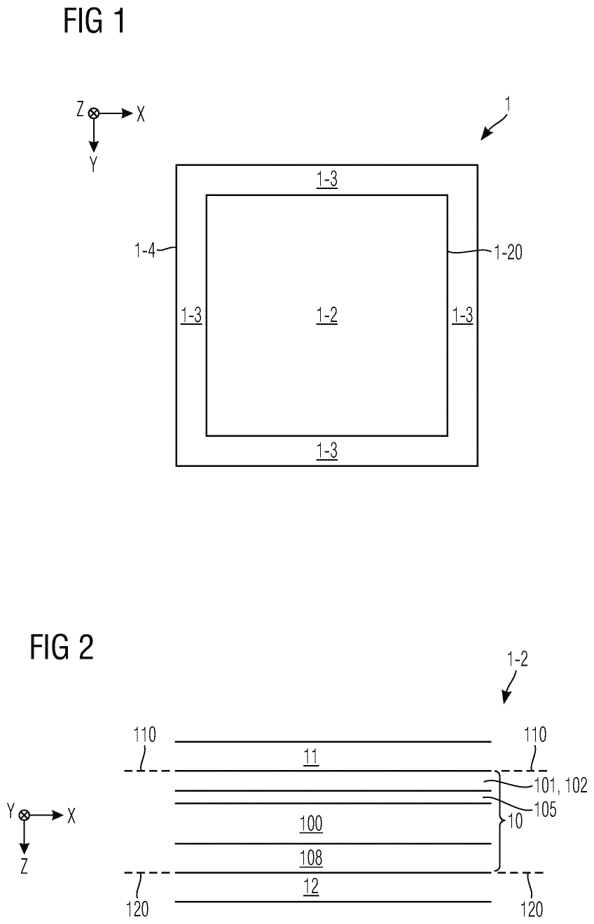

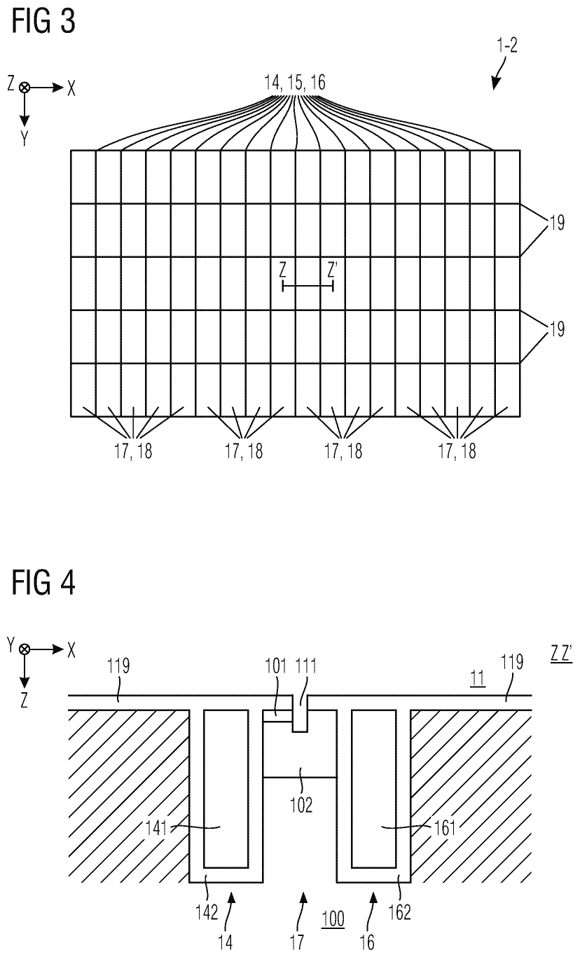

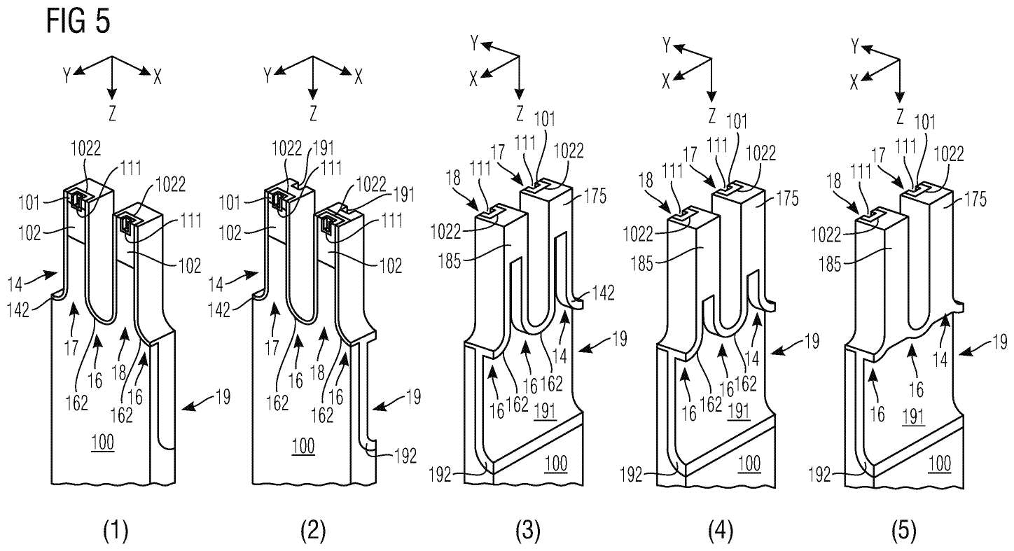

FIGS. 1 and 3 schematically and exemplary illustrate sections of a horizontal projection of a power semiconductor device 1 in accordance with one or more embodiments. FIGS. 2 and 4 schematically and exemplary illustrate sections of vertical cross-sections in accordance with one or more embodiments. FIGS. 1 to 4 illustrates general aspects of the power semiconductor device 1. The power semiconductor device 1 illustrated in these FIGS. 1 to 4 may be configured in accordance with the illustrations of FIGS. 5 to 8 and/or may be produced in accordance with the method illustrated in FIGS. 9-1 to 9-14.

Referring first to FIGS. 1 and 2, the power semiconductor device 1 comprises a semiconductor body 10 coupled to a first load terminal 11 at a first side 110 (cf. FIG. 2) and a second load terminal 12 at a second side 120 that is opposite to the first side 110 with respect to the vertical direction Z.

The semiconductor body 10 may exhibit a thickness corresponding to the distance between the first side 110 and the second side 120 along the vertical direction Z.

The power semiconductor body 10 comprises an active region 1-2 configured to

conduct a load current between the first load terminal 11 and the second load terminal 12.

As illustrated in FIG. 2, the semiconductor body 10 may be sandwiched between the first load terminal 11 and the second load terminal 12.

The power semiconductor device 1 may exhibit a vertical configuration, according to which the load current in active region 1-2 follows a path substantially in parallel to the vertical direction Z.

At a border line 1-20, the active region 1-2 transitions into an edge termination region 1-3, which is in turn terminated by a chip edge 1-4. That is, the edge termination region 1-3 surrounds the active region 1-2.

Herein, the terms ‘active region’ and ‘edge termination region’ are used with a technical context the skilled person typically associates with these terms. Accordingly, the active region's purpose is primarily to ensure load current conduction, whereas the edge termination region 1-3 is configured to reliably terminate the active region 1-2, e.g. in terms of courses of the electric field during conduction state and during blocking state.

The present specification primarily relates to the configuration of the active region 1-2 and the production thereof.

As illustrated in FIG. 2, at the first side 110 and electrically isolated from the first load terminal 11 and the second load terminal 12, the power semiconductor device 1 comprises source regions 101 of the first conductivity type and body regions 102 of the second conductivity type forming first semiconductor channel structures, e.g., as illustrated in FIG. 4. For example, each source region 101 is electrically connected to the first load terminal 11, e.g., based on a respective contact plug 111. The body regions 102 may isolate the source regions 101 from a drift region 100. The drift region 100 is of the first conductivity type. The body regions 102 are connected to the first load terminal 11, e.g., also based on a respective contact plug 111 or based on a respective planar contact.

At the first side 110 and in the active region 1-2, first trenches 14, 16 extend in the semiconductor body 10 along the vertical direction Z. For example, the first trenches 14, 16 extend to a first depth along the vertical direction Z into the semiconductor body 10. The first trenches 14, 16 can be arranged adjacent to each other along the first lateral direction X and extend along the second lateral direction Y, thereby laterally confining mesas 17, 18 of the semiconductor body 10 exhibiting a respective stripe configuration, as also illustrated in FIG. 3. At least some of the first trenches are control trenches 14 housing a respective control trench electrode 141 for controlling the load current in first semiconductor channel structures formed in the respective adjacent mesa portion 17. The first trenches 14, 16 may be arranged in parallel to each other.

The first trenches 14, 16 may further comprise source trenches 16 housing a respective source trench electrode 161 electrically connected to the first load terminal 11. The trench electrodes 141, 161 are electrically isolated from the semiconductor body based on a respective trench insulator 162, 142. The first trenches may additionally include trenches 15 of a further type, e.g., trenches that house a floating trench electrode and/or a trench electrode connected to another control potential than the control trench electrodes 141.

The mesas confined by the first trenches 14, 15 and 16 may comprise first type mesas 17 and second type mesas 18, for example. In general, any configuration of mesa is as well as any combination of different configurations among the mesas are possible. The first type mesas 17 and the second type mesas 18 may each comprise a portion of the body region 102.

Herein, first type mesas 17 denote mesas that are configured to contribute to load current conduction and in which the load current share may be controlled based on inducing or, respectively, cutting-off an inversion channel in the body region 102. For example, FIG. 4 illustrates an exemplary configuration of the first type mesa 17. There, the inversion channel is induced in the body region 102 by setting the adjacent control trench electrode 141 to a corresponding potential, e.g., via applying a voltage between a (non-illustrated) control terminal electrically connected to the control trench electrode 141 and the first load terminal 11 electrically connected to the contact plug 111 which is arranged in electrical contact with both the source region 101 and the body region 102. For example, the source region 101 may be arranged only in proximity to the control trenches 14 or expand over the whole first type mesas 17 while being only interrupted by the contact plug 111 connecting the body region 102.

Second type mesas 18 differ from first type mesas 17, e.g., in that these are not electrically connected to the first load terminal 11 and/or in that these do not comprise a source region and/or in that these are not laterally confined by at least one of the control trenches 14.

Thus, based on the arrangement of first trenches 14, 15, 16 and first and second type mesas 17, 18 along the first lateral direction X, diverse trench-mesa-patterns may be formed at the first side 110. Herein, the specifically chosen trench-mesa-pattern is of less relevance.

As illustrated in FIG. 4, the trench electrodes 141, 161 of the first trenches 14, 16 and the semiconductor body 10 may be isolated from the first load terminal 11 based on at least one insulation layer 119. For electrically connecting the first type mesas 17 and, if applicable, the second type mesas 18, with the first load terminal 11, the contact plugs 111 penetrate the insulation layer 119. It shall be understood, though, that the electrical connection between the first load terminal 11 and the first type mesas 17 and, if applicable, the second type mesas 18, may be established based on flat contacts or other alternatives to the contact plugs 111.

Optionally, as illustrated in FIG. 2, between the first channel structures (101, 102) and the drift region 100, a barrier region 105 may be formed. The barrier region may be of either the first or the second conductivity type, and may either exhibit a spatially homogenous dopant concentration or a laterally and/or vertically varying dopant concentration. Similar to the specifically chosen trench-mesa-pattern, the optionally provided barrier region 105 is of less significance herein.

The drift region 100 extends along the vertical direction Z until interfacing with an emitter region 108 electrically connected to the second load terminal 12. The emitter region 108 can be of the first conductivity type, e.g., in when the device 1 is configured as a MOSFET, or of the second conductivity type, e.g., in when the device 1 is configured as an IGBT, or of both conductivity types, e.g., in when the power semiconductor device 1 is configured as an RC-IGBT.

Optionally, between the drift region 100 and the emitter region 108, there may be arranged a (non-illustrated) field stop region and/or a buffer region.

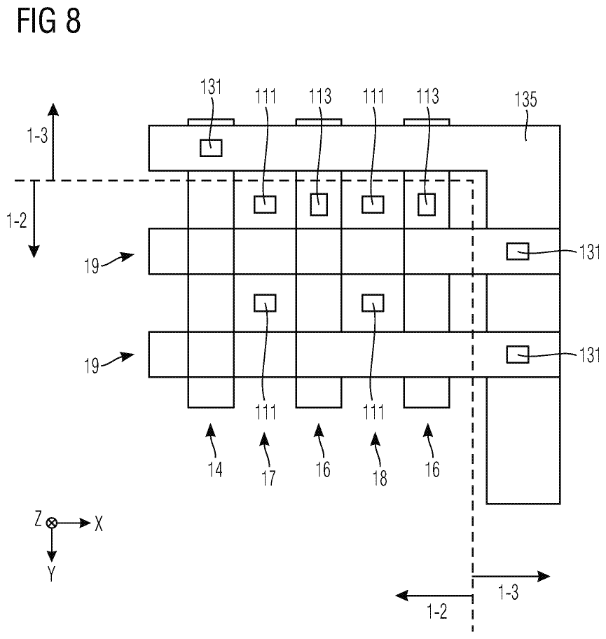

As schematically illustrated in FIGS. 3 and 8, and as illustrated in more detail in FIGS. 5 to 7, the power semiconductor device 1 may further comprise, at the first side 110 and in the active region 1-2, a deep cross trench 19 extending into the semiconductor body along the vertical direction Z below bottoms of the first trenches 14, 16 and traversing a region corresponding to lower vertical projections of portions 175, 185 in between the mesas 17, 18. These mesa portions 175 and 185 are illustrated in FIGS. 5 to 7.

As illustrated in FIG. 3 and FIG. 8, the power semiconductor device 1 may comprise more than one deep cross trench 19. For example, several deep cross trenches 19 are arranged adjacent to each other along the second lateral direction Y in the active region 1-2 and extend along the first lateral direction X, i.e., perpendicular to the first trenches 14, 16. However, in other embodiments any angle, e.g. in a range from 45° to 90° , between the deep cross trenches 19 and the first trenches 14, 16 is possible. For example, the deep cross trenches may be aligned in parallel to each other. For example, both the first trenches 14, 16 and the deep cross trenches 19 extend substantially throughout the entire active region 1-2 of the power semiconductor device 1. Thereby, the first trenches 14, 16 and the deep cross trenches 19 may form a trench grid, as best illustrated in FIG. 3. Accordingly, the first and second type mesas 17, 18 may be divided into respective columnar subsections based on the trench grid formed by the first trenches 14, 16 and the deep cross trenches 19. In other words, based on the deep cross trenches 19, the effective volume at the first side 110 where load current flow is possible is limited.

The present specification primarily relates to the exemplary configurations of the deep cross trenches and to corresponding production methods. In the following, it will be referred to “the” deep cross trench 19, wherein it shall be understood that the corresponding statements may apply to each deep cross trench 19 present in the active region 1-2.

In an embodiment, the deep cross trench 19 includes a deep cross trench electrode 191 and a deep cross trench insulator 192 electrically insulating the deep cross trench electrode 191 from the semiconductor body 10. Further, each of said control trenches 14 includes a control trench insulator 142 electrically insulating the control trench electrode 141 from the semiconductor body 10. The thickness of the deep cross trench insulator 192 amounts to at least 150% of the average thickness of the control trench insulators 142. Further trench insulators 162 may have a same thickness as the control trench insulators 142. The thickness of the deep cross trench insulator 192 may amount to at least 150% of the average thickness of the further trench insulators 162. The deep cross trench electrode 191 may be arranged fully or partly below control trench electrode 141. The deep cross trench electrode 191 may vertically overlap or not overlap the control trench electrode 141.

In another embodiment, which may be combined with the embodiment described in the preceding paragraph, at least an upmost portion of the deep cross trench 19 is made of an insulating material 192, said upmost portion vertically overlapping with at least the average upmost quarter of the first trenches 14, 16 or even the entire average vertical extension of the first trenches 14, 16. For example, the deep cross trench 19 may be filled with the insulating material 192 from first side 110 to a second depth along the vertical direction Z. The deep cross trench electrode 191 may for example be arranged below the second depth. More specifically, the deep cross trench 19 may be filled with the insulating material 192 above the second depth and the deep cross trench electrode 191 below the second depth. In this example, the deep cross trench electrode 191 does not extend above the second depth. The second depth may be at least 25% of the first depth, or at least 50% of the first depth, or at least 80% of the first depth. In a very advantageous example, the second depth equals the first depth (e.g. in a range of +/−5%).

In a yet another embodiment, the deep cross trench 19 is devoid of any trench electrode. In this embodiment, the deep cross trench 19 may for example be completely filled with the insulating material 192.

Regarding the embodiments illustrated in FIG. 5, both the first type mesa 17 and the second type mesa 18 are electrically contacted with the first load terminal 11 based on contact plugs 111. The first type mesa 17 includes the source region 101 and is laterally confined by one of the control trenches 14 and one of the source trenches 16. The second type mesa 18 does not include a source region 101, but the body region 102, and is laterally confined by two of the source trenches 16. Each body region 102 may comprise a body contact region 1022 with increased dopant concentration for improving the electrical contact to the respective contact plug 111.

In accordance with variant (1) of FIG. 5, the deep cross trench 19 is devoid of any trench electrode. Rather, the deep cross trench 19 consists of an electrically insulating material.

In accordance with variant (2) of FIG. 5, the deep cross trench 19 includes a deep cross trench electrode 191 and, accordingly, also the deep cross trench insulator 192.

Variants (2) to (5) of FIG. 5 illustrate exemplary configurations of the deep cross trench electrode 191. According to variants (2) to (4), the deep cross trench electrode 191 extends below bottoms of the first trenches 14, 16, but also vertically overlaps with the trench electrodes 141, 161 of the first trenches 14, 16, e.g., for at least the lower 10% of the average total vertical extension of the first trenches 14, 16 (cf. variant (4)), or for up to the lower 80% of the average total vertical extension of the first trenches 14, 16 (cf. variant (3)), or even entirely vertically overlaps with the trench electrodes 141, 161 of the first trenches 14, 16, e.g., also terminating at the first side 110 (cf. variant (2)). As the deep cross trench electrode extends to the surface of the semiconductor body 10, an additional oxide layer (not shown) may insulate it. Alternatively, regarding variant (5), the deep cross trench electrode 191 is entirely arranged, at least within the active region 1-2, below the bottoms of the first trenches 14, 16, and does not vertically overlap with the trench electrodes 141, 161 of the first trenches 14, 16. In this case, the portions 175, 185 in between the mesas 17, 18 along the second lateral direction Y corresponding to vertical projections of the deep cross trench electrode 191 below them may be filled with an insulating material, for example.

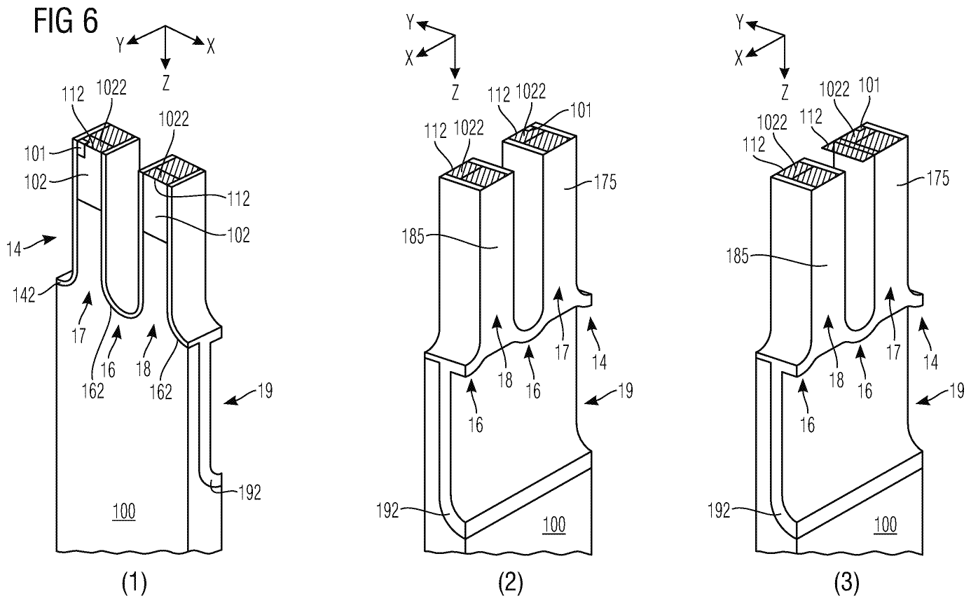

Irrespective of the configuration of the deep cross trench electrode 191, FIG. 6 illustrates another possibility of electrically contacting the first and second type mesas 17, 18. There, no contact plugs 111 are employed, but first contacts 112, which may be embodied as flat contacts, to establish an electrical connection between the first semiconductor channel structures and the first load terminal 11. For example, when using first contacts 112 embodied as flat contacts, the mesas 17 and 18 must not necessarily be equipped with a respective contact groove for the contact plug, which may facilitate processing of the device 1. For example, the mesas 17, 18 can form a substantially horizontal portion of the surface of the first side 110 and are not equipped with a contact groove. For example, the first contacts 112 may exhibit an area in the range of 600 nm (e.g., the mesa width in the first lateral direction X) * at least 800 nm (e.g., length in the second lateral direction Y), which is illustrated in both variants (1) and (2) of FIG. 6. In another, the first contacts 112 may exhibit an area in the range of only 600 nm (e.g., the mesa width in the first lateral direction X) * at less than 600 nm (e.g., length in the second lateral direction Y), due to a thicker oxide of the deep cross trench insulator 192. In accordance with variant (3) of FIG. 6, the width of at least one of the first contacts 112 is extended such that the first contact 112 not only electrically contacts the first type mesa 17 (i.e., its source region 101 and body region 102), but also the source trench electrode 161 of source trench 16 adjacent to the first type mesa 17. To this end, each of the first contacts 112 may laterally overlap with a respective one of said source trench electrodes 161.

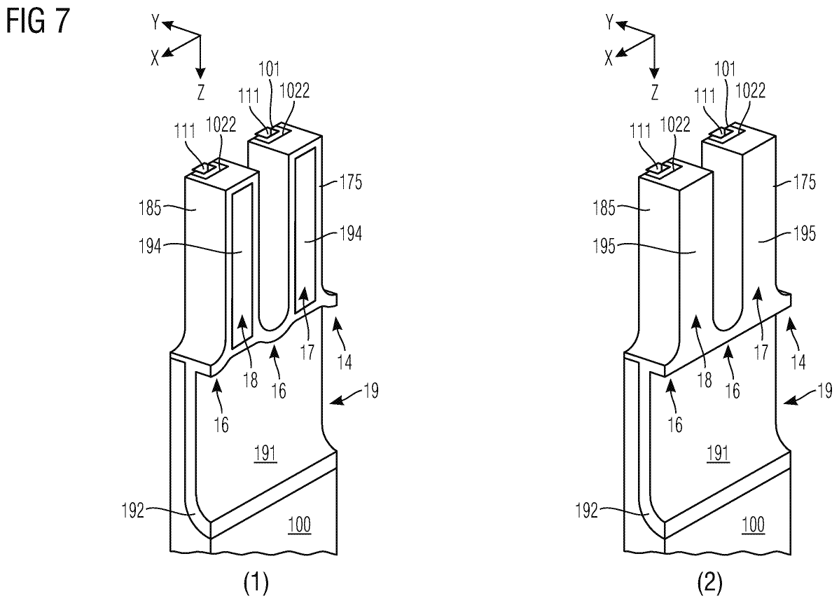

FIG. 7 illustrates further variants of the deep cross trench 19. In accordance with both variants (1) and (2), the deep cross trench electrode 191 is, at least within the active region 1-2, exclusively arranged below the bottoms of the first trenches 14, 16. In variant (1), the portions 175, 185 of the mesas 17, 18 corresponding to vertical projections of the deep cross trench 19 below thereof are equipped with a respective floating electrode 194. That is, the floating electrodes 194 are neither electrically connected with the deep cross trench electrode 191 nor with the trench electrodes 141, 161 of the first trenches 14, 16. In variant (2), the portions 175, 185 of the mesas 17, 18 corresponding to vertical projections of the deep cross trench 19 below thereof are entirely filled with an insulating material, such as an oxide.

FIG. 8 illustrates an exemplary contacting scheme. For example, a gate runner 135 is arranged in the edge termination region 1-3 and electrically connected with the control trench electrodes 141. For example, the electrical connection is established in that the trench electrodes 141 extend, along/against the second lateral direction Y from the active region 1-2 into the edge termination region 1-3 where control contact plugs 131 or other electrically conductive means extend from the gate runner 135 along the vertical direction Z to contact the respective control trench electrode 141. To establish the electrical connection between the source trench electrodes 161, further contact plugs 113 may be employed within the active region 1-2 in addition to the contact plugs 111 employed for contacting the first and second type mesas 17, 18 within the active region 1-2. Alternatively, first contacts 112, e.g., embodied as planar contacts, may be used for contacting the mesas 17, 18 and the source trench electrodes 161. According to some embodiments, planar contacts may also be used to connect the control trench electrode 141 and/or the deep cross trench electrode 191 to their respective potential.

Still referring to FIG. 8, in an embodiment, the deep cross trench electrode 191 is electrically connected with the control trench electrodes 141. Hence, the deep cross trench electrode 191 and the control trench electrodes 141 may exhibit the same electrical potential. That is, in an embodiment, as a control voltage may be applied to the deep cross trench electrode 191, the deep cross trench electrode 191 can be used for controlling the power semiconductor device 1.

Still referring to FIG. 8, outermost mesas 17, 18 neighboring the edge termination region 1-3 along the first lateral direction X may be devoid of any contact to the first load terminal 11. This may further reduce a drain of charge carriers, as the charge carriers are to move relatively free along the first lateral direction X. In contrast, the flow of charge carriers along the second lateral direction Y is relatively restricted by the deep cross trenches 192. Therefore, outermost mesas 17, 18 neighboring the edge termination region 1-3 along the second lateral direction Y may be connected to the first load terminal 111 while not or only slightly increasing the drain of charge carriers.

For example, the deep cross trench 19 may extend from the active region 1-2 along/against the first lateral direction X into the edge termination region 1-3. At least in the portion arranged in the edge termination region 1-3, the deep cross trench electrode 191 also extends above the bottoms of the first trenches close to the first side 110 (as exemplarily illustrated in FIG. 5, variant (2)) such that it may there be contacted with one of the control contact plugs 131. The configuration of the deep cross trench electrode 191 in the active region 1-2 may be different, though, e.g., as illustrated in FIG. 5, variant (3), (4) or (5).

The features described in the following may be applied to each of the above described embodiments.

For example, the thickness of the deep cross trench insulator 192 amounts to at least 150% of the average thickness of the control trench insulators 142. The deep cross trench insulator thickness may even be greater than 190% of the average thickness of the control trench insulators 142. For example, the average thickness of the control trench insulators 142 is in the range of 80 nm to 120 nm, and the deep cross trench insulator thickness is in the range of 160 nm to 240 nm.

As explained above, the deep cross trench 19 may extend substantially perpendicularly with respect to the first trenches 14, 16 and the mesas 17, 18. Furthermore, the deep cross trench 19 may exhibit a total vertical extension within the range of 150% to 250% of the average total vertical extension of the first trenches 14, 16. Furthermore, the deep cross trench 19 may exhibit a total lateral width within the range of 50% to 150% of the average total lateral width of the first trenches 14, 16.

If present, the deep cross trench electrode 191 is electrically connected with one of the following: the control trench electrodes 141, the first load terminal 11 or another electrical potential, e.g., a second control potential. Alternatively, the deep cross trench electrode 191 may be floating.

As explained with respect to the example of FIG. 8, in an embodiment, the deep cross trench 19 at least partially extends into the edge termination region 1-3, wherein electrical connection of the deep cross trench electrode 191 is established in the edge termination region 1-3.

Furthermore, the device 1 may comprise not only one deep cross trench 19, but several additional deep cross trenches 19, wherein the deep cross trenches 19 may be arranged adjacent to each other along the second lateral direction Y. Each deep cross trench 19 may be configured as described above. Furthermore, the average distance between adjacent deep cross trenches 19 can be within the range of 50% to 200% of the average distance between adjacent first trenches 14, 16.

The optionally provided barrier region 105 may have a greater dopant concentration as compared to the drift region 100 and/or a total vertical extension within the range of 30 to 150% of the total average vertical extension of the first trenches 14, 16. The barrier region 105 may be arranged above the bottom of the deep cross trench 19 and below the bottoms of the first trenches 14, 16. The barrier region 105 may be arranged vertically centered around the bottoms of the first trenches 14, 16 or the bottoms of the deep cross trenches 19. In some embodiments, the barrier region 105 may not overlap with the bottoms of the first trenches 14, 16 or the bottoms of the deep cross trench 19. In some embodiments, the barrier region 105 may not overlap with the bottoms of both the first trenches 14, 16 and the deep cross trench 19. In this case the barrier region 105 may be arranged in-between the bottoms of the first trenches 14, 16 and the bottoms of the deep cross trench 19 or in depth between 30% and 90% of the first trenches 14, 16. In general, the barrier region 105 may be arranged in a depth greater than 30% of the depth of the first trenches 14, 16 and in a depth smaller than 150% of the depth of the deep cross trench 19.

The first trenches 14, 16 may be arranged in parallel to each other. The deep cross trenches 19 may be arranged in parallel to each other and perpendicular to the first trenches 14, 16.

Presented herein are also methods of producing a power semiconductor device.

According to an embodiment, a method of producing a power semiconductor device comprises forming the following components: a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. The method is carried out such that: The deep cross trench includes a deep cross trench electrode and a deep cross trench insulator electrically insulating the deep cross trench electrode from the semiconductor body; each of said control trenches includes a control trench insulator electrically insulating the control trench electrode from the semiconductor body; and such that the thickness of the deep cross trench insulator amounts to at least 150% of the average thickness of the control trench insulators.

According to another embodiment, a method of producing a power semiconductor device comprises forming the following components: a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal; at the first side and in the active region, first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; at the first side and in the active region, a deep cross trench extending into the semiconductor body along the vertical direction below bottoms of the first trenches and traversing a region corresponding to lower vertical projections of portions of the mesas. The method is carried out such that at least an upmost portion of the deep cross trench is made of an insulating material, said upmost portion vertically overlapping with at least the average upmost quarter of the first trenches.

Further embodiments of the methods described above correspond to the embodiments and exemplary configurations of the power semiconductor device 1 presented above. In the following, based on FIGS. 9-1 to 9-14, an exemplary method will be explained, using terminology and reference signs as employed above.

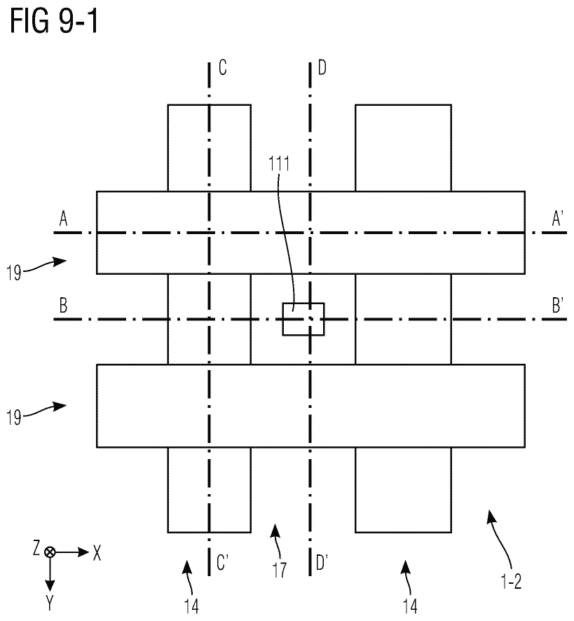

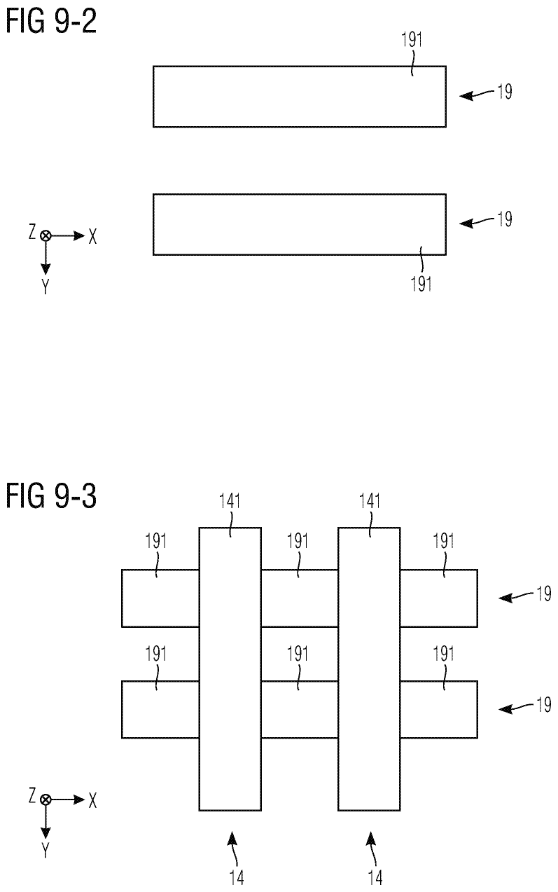

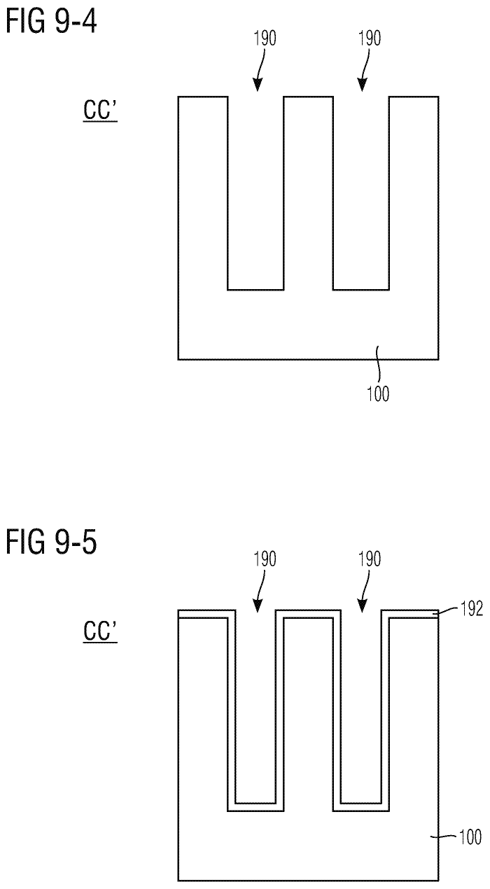

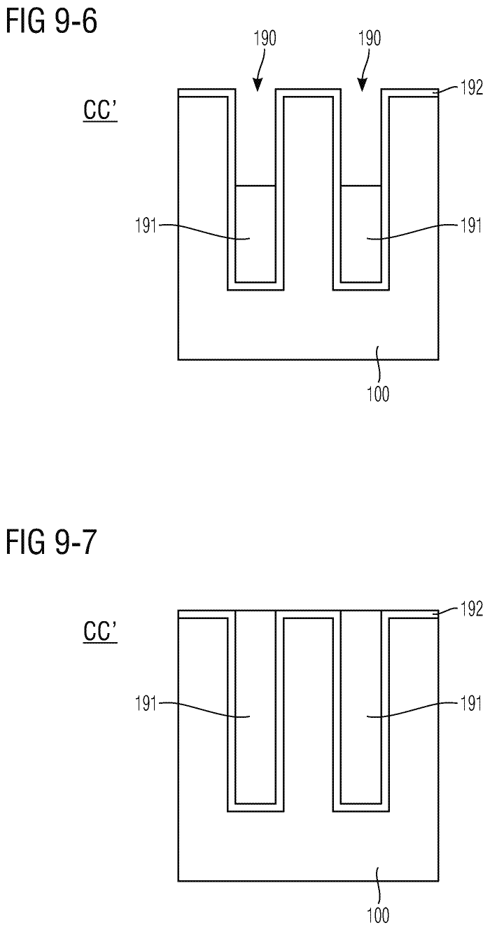

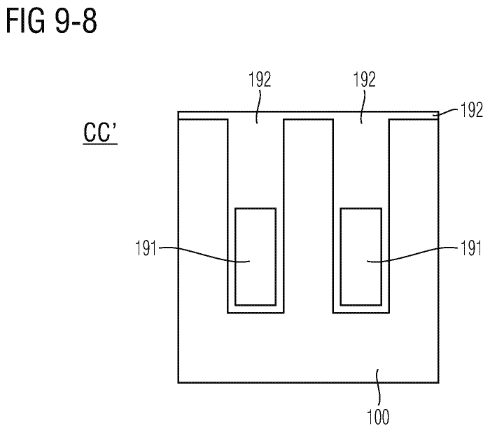

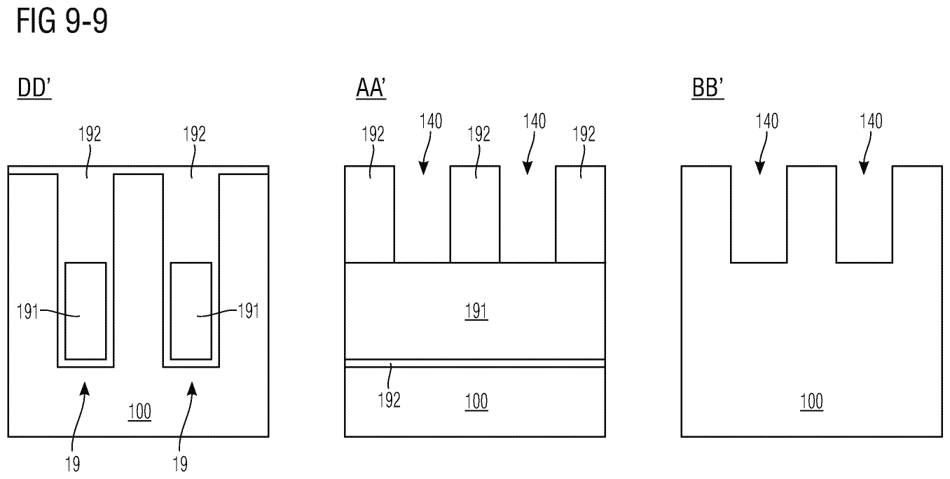

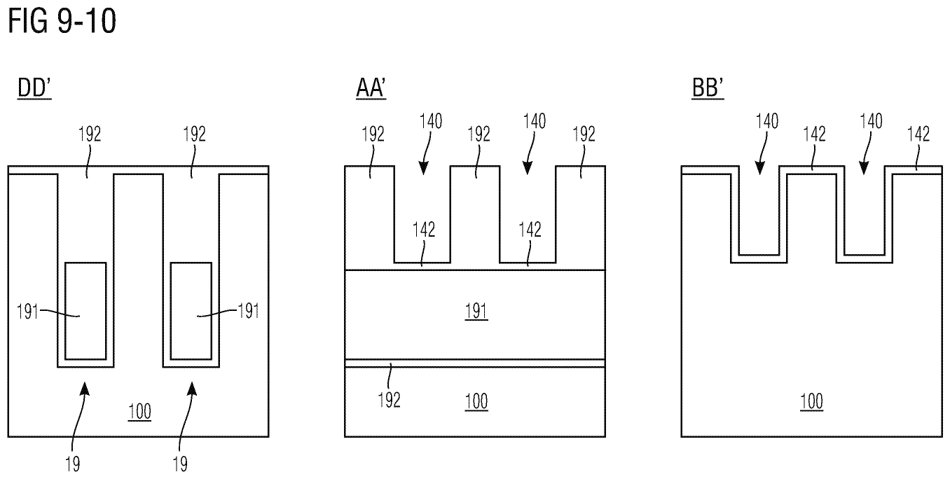

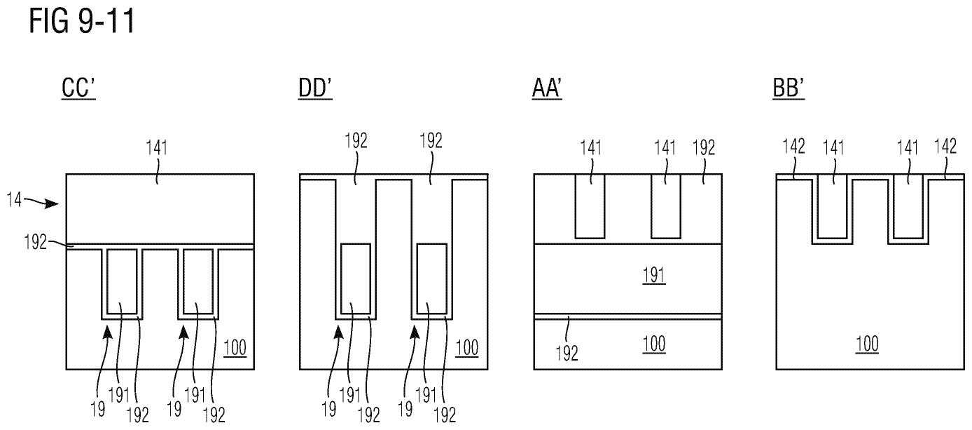

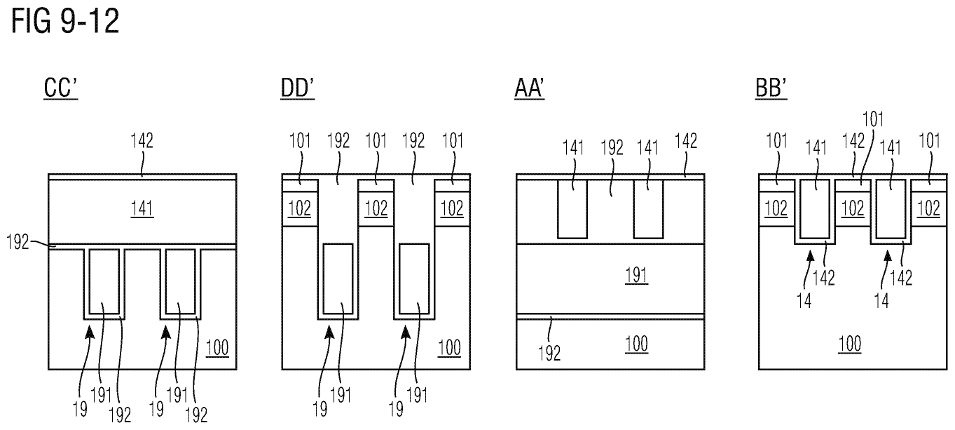

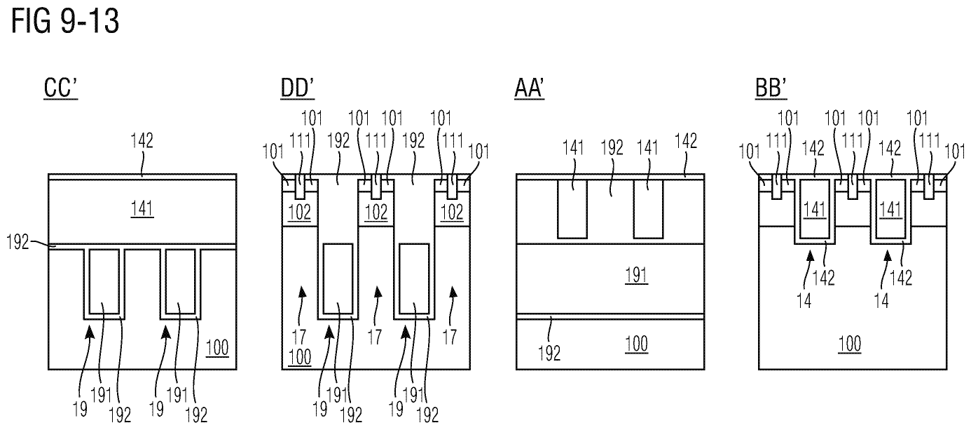

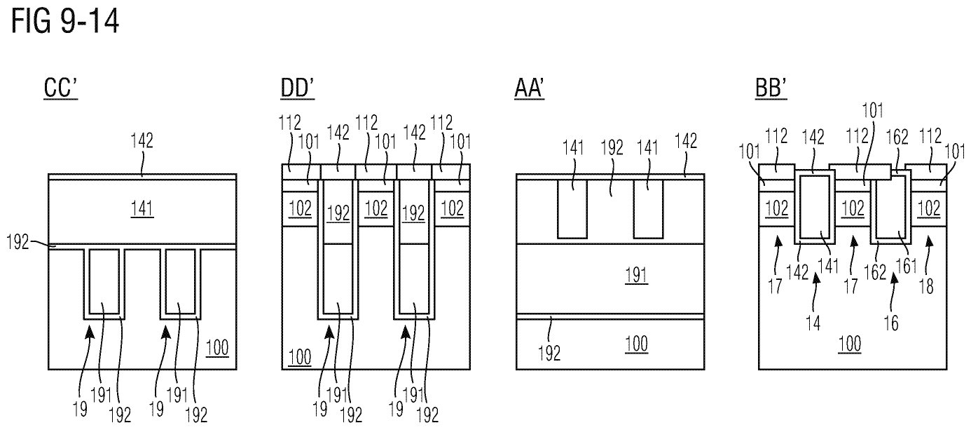

FIG. 9-1 illustrates a section of a horizontal projection of the active region 1-2, where two deep cross trenches 19 extend along the first lateral direction X and two control trenches 14 extend perpendicular thereto along the second lateral direction Y. The first type mesa 17 laterally confined by the two control trenches 14 and the two deep cross trenches 19 below thereof is electrically connected with the first load terminal 11 via the contact plug 111. The dashed lines AA′, BB′, CC′ and DD′ indicate positions of cross-sections illustrated in the subsequent drawings.

For example, as illustrated in FIG. 9-2, at a vertical level corresponding to the deep cross trench electrodes 191, a stripe cell structure is provided, wherein, e.g., the deep cross trench electrodes 191 may be electrically connected with a further control potential independent of the potential of the control trench electrodes 141, e.g., so as to be able to independently control the carrier confinement. As illustrated in FIG. 9-3, at a vertical level corresponding to the control trenches 14, a grid cell structure is provided, including at least the control trench electrodes 141 and portions of the deep cross trenches 19, which may include portions of deep cross trench electrode 191, another electrode and/or an insulating material (cf. explanations with respect to FIGS. 5-7).

According to the processing stage illustrated in FIG. 9-4, deep trenches 190 are formed where the deep cross trenches 19 shall later be implemented. This processing stage may include a trench lithography processing step and/or a trench etch processing step, and/or further processing steps, e.g., related to the use of a mask (e.g., mask stripping and mask cleaning).

According to the processing stage illustrated in FIG. 9-5, the deep cross trench insulator 192 is formed, e.g., based on a deposition processing step or thermal oxide growth step.

According to the processing stage illustrated in FIG. 9-6 and FIG. 9-7, the deep cross trench electrode 191 is formed, e.g., based on a poly-silicon deposition processing step and a subsequent poly-silicon recess etch processing step.

According to the processing stage illustrated in FIG. 9-8, the deep cross trench insulator 192 is further formed, namely above the deep cross trench electrodes 191, e.g., based on a deposition processing step.

According to the processing stage illustrated in FIG. 9-9, trenches 140 for the first trenches 14, 16 are formed. This processing stage may include a trench lithography processing step and/or a trench etch processing step, and/or further processing steps, e.g., related to use of a mask (e.g., mask stripping and mask cleaning). It is noted that the process is only illustrated for the control trenches 14, wherein it shall be understood that the source trenches 16 or other type trenches 15, e.g. floating trenches 15, may be formed in the same manner

According to the processing stage illustrated in FIG. 9-10, the first trench insulators 142 are formed, e.g., based on a deposition processing step. Here, it is noted that the oxide grows faster/thicker on the poly-silicon material of the deep cross trench electrode 191 as compared to the growth on “normal” silicon material. This fact may be beneficially exploited, as the insulation with respect to the deep cross trench electrode 191 may need to withstand higher voltages. Furthermore, the controllability of the load current by variation of the control voltage may be increased.

According to the processing stage illustrated in FIG. 9-11, the first trench electrodes 141, 161 are formed, e.g., based on a poly-silicon deposition processing step and a subsequent poly-silicon recess etch processing step.

According to the processing stage illustrated in FIG. 9-12, the source regions 101 and the body regions 102 are formed, i.e., the first type mesas 17. Also, the second type mesas 18 may be formed. This stage may include implantation processing steps, which may be masked for the source regions 101 and which may be carried out as blanket implantation for the body regions 102, in accordance with an example.

According to the processing stage illustrated in FIG. 9-13, the contact plugs 111 may be formed for electrically contacting the first type mesas 17. The processing stage illustrated in FIG. 9-14 is an alternative to the processing stage illustrated in FIG. 9-13; here, instead of the contact plugs 111, first contacts 112 embodied as planar contacts are formed. As explained above, these may facilitate processing of the device 1, in particular in case of small width mesas. Here, it is assumed that one of the first trenches is a source trench 16 whose source trench electrode 161 is electrically contacted by one of the first contacts 112 that likewise contacts the adjacent first type mesa 17.

In the above, embodiments pertaining to power semiconductor device, such as IGBTs, RC IGBTs and derivatives thereof, and corresponding processing and control methods were explained. For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride

(AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixCl-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising”, “exhibiting” and the like are open ended terms that indicate the presence of stated elements or features, but do not preclude additional elements or features.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A power semiconductor device, comprising:
a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal;
at the first side and in the active region, a plurality of first trenches extending in the semiconductor body along the vertical direction, wherein the first trenches are arranged adjacent to each other along a first lateral direction and extend along a second lateral direction, thereby laterally confining mesas of the semiconductor body exhibiting a respective stripe configuration, wherein at least some of the first trenches are control trenches housing a respective control trench electrode for controlling the load current in first semiconductor channel structures formed in the respective adjacent mesa portion; and
at the first side and in the active region, a deep cross trench extending into the semiconductor body along the vertical direction below bottoms of the first trenches and traversing a region corresponding to lower vertical projections of portions of the mesas,
wherein:
the deep cross trench includes a deep cross trench electrode and a deep cross trench insulator electrically insulating the deep cross trench electrode from the semiconductor body;
each of the control trenches includes a control trench insulator electrically insulating the control trench electrode from the semiconductor body; and
the thickness of the deep cross trench insulator amounts to at least 150% of an average thickness of the control trench insulators.

2. The power semiconductor device of claim 1, wherein at least an upmost portion of the deep cross trench is made of an insulating material, the upmost portion vertically overlapping with at least an average upmost quarter of the first trenches.

3. The power semiconductor device of claim 2, wherein the upmost portion vertically overlaps with at least the entire average vertical extension of the first trenches.

4. The power semiconductor device of claim 3, wherein the upmost portion vertically overlaps with at least the entire average vertical extension of the first trenches.

5. The power semiconductor device of claim 4, wherein the deep cross trench is devoid of any trench electrode.

6. The power semiconductor device of claim 1, further comprising first contacts to establish an electrical connection between the first semiconductor channel structures and the first load terminal.

7. The power semiconductor device of claim 6, wherein the first trenches further comprise source trenches including a respective source trench electrode electrically connected to the first load terminal, wherein each of the first contacts laterally overlaps with a respective one of the source trench electrodes.

8. The power semiconductor device of claim 6, wherein the first contacts are embodied as planar contacts.

9. The power semiconductor device of claim 1, wherein the mesas form a substantially horizontal portion of the surface of the first side and are not equipped with a contact groove.

9. The power semiconductor device of claim 1, wherein the deep cross trench extends substantially perpendicularly with respect to the first trenches and the mesas.

11. The power semiconductor device of claim 1, wherein the deep cross trench exhibits a total vertical extension within the range of 150% to 250% of the average total vertical extension of the first trenches, and/or wherein the deep cross trench exhibits a total lateral width within the range of 50% to 150% of the average total lateral width of the first trenches.

12. The power semiconductor device of claim 1, wherein the deep cross trench includes a deep cross trench electrode, wherein the deep cross trench electrode is electrically connected with the control trench electrodes, the first load terminal, or another electrical potential.

13. The power semiconductor device of claim 12, further comprising an edge termination region surrounding the active region, wherein the deep cross trench at least partially extends into the edge termination region, and wherein electrical connection of the deep cross trench electrode is established in the edge termination region.

14. The power semiconductor device of claim 1, further comprising additional deep cross trenches, wherein the deep cross trench and the additional deep cross trenches are arranged adjacent to each other along the second lateral direction.

15. The power semiconductor device of claim 14, wherein the average distance between adjacent deep cross trenches is within the range of 50% to 200% of the average distance between adjacent first trenches.

16. The power semiconductor device of claim 1, wherein in the active region, the semiconductor body comprises a drift region of a first conductivity type and a barrier region of either the first conductivity type or a second conductivity type, and wherein the barrier region couples at least some of the first semiconductor channel structures to the drift region.

17. The power semiconductor device of claim 16, wherein the barrier region exhibits a greater dopant concentration as compared to the drift region and/or a total vertical extension within the range of 30% to 150% of the total average vertical extension of the first trenches.

18. The power semiconductor device of claim 1, wherein the mesas include first type mesas and second type mesas, wherein the first type mesas comprise the first semiconductor channel structures controlled by the control trench electrodes, wherein at least one of the second type mesas is electrically connected to the first load terminal and not controlled by the control trench electrodes, and wherein the deep cross trench is arranged adjacent to at least one second type mesa.

19. A power semiconductor device, comprising:
a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal;
at the first side and in the active region, a plurality of first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion; and
at the first side and in the active region, a deep cross trench extending into the semiconductor body along the vertical direction below bottoms of the first trenches and traversing a region corresponding to lower vertical projections of portions of the mesas,
wherein at least an upmost portion of the deep cross trench is made of an insulating material, the upmost portion vertically overlapping with at least the average upmost quarter of the first trenches.

20. The power semiconductor device of claim 19, wherein the upmost portion vertically overlaps with at least the entire average vertical extension of the first trenches.

21. The power semiconductor device of claim 19, wherein the deep cross trench is devoid of any trench electrode.

22. The power semiconductor device of claim 19, further comprising first contacts to establish an electrical connection between the first semiconductor channel structures and the first load terminal.

23. The power semiconductor device of claim 22, wherein the first trenches further comprise source trenches including a respective source trench electrode electrically connected to the first load terminal, and wherein each of the first contacts laterally overlaps with a respective one of the source trench electrodes.

24. The power semiconductor device of claim 22, wherein the first contacts are embodied as planar contacts.

25. The power semiconductor device of claim 19, wherein the mesas form a substantially horizontal portion of the surface of the first side and are not equipped with a contact groove.

26. The power semiconductor device of claim 19, wherein the deep cross trench extends substantially perpendicularly with respect to the first trenches and the mesas.

27. The power semiconductor device of claim 19, wherein the deep cross trench exhibits a total vertical extension within the range of 150% to 250% of the average total vertical extension of the first trenches, and/or wherein the deep cross trench exhibits a total lateral width within the range of 50% to 150% of the average total lateral width of the first trenches.

28. The power semiconductor device of claim 19, wherein the deep cross trench includes a deep cross trench electrode, and wherein the deep cross trench electrode is electrically connected with the control trench electrodes, the first load terminal , or another electrical potential.

29. The power semiconductor device of claim 28, further comprising an edge termination region surrounding the active region, wherein the deep cross trench at least partially extends into the edge termination region, and wherein electrical connection of the deep cross trench electrode is established in the edge termination region.

30. The power semiconductor device of claim 19, further comprising additional deep cross trenches, wherein the deep cross trench and the additional deep cross trenches are arranged adjacent to each other along the second lateral direction.

31. The power semiconductor device of claim 30, wherein the average distance between adjacent deep cross trenches is within the range of 50% to 200% of the average distance between adjacent first trenches.

32. The power semiconductor device of claim 19, wherein in the active region, the semiconductor body comprises a drift region of a first conductivity type and a barrier region of either the first conductivity type or a second conductivity type, and wherein the barrier region couples at least some of the first semiconductor channel structures to the drift region.

33. The power semiconductor device of claim 32, wherein the barrier region exhibits a greater dopant concentration as compared to the drift region and/or a total vertical extension within the range of 30% to 150% of the total average vertical extension of the first trenches.

34. The power semiconductor device of claim 19, wherein the mesas include first type mesas and second type mesas, wherein the first type mesas comprise the first semiconductor channel structures controlled by the control trench electrodes, wherein at least one of the second type mesas is electrically connected to the first load terminal and not controlled by the control trench electrodes, and wherein the deep cross trench is arranged adjacent to at least one second type mesa.

35. A method of forming a power semiconductor device, the method comprising:
forming a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal;
at the first side and in the active region, forming a plurality of first trenches extending in the semiconductor body along the vertical direction, wherein the first trenches are arranged adjacent to each other along a first lateral direction and extend along a second lateral direction, thereby laterally confining mesas of the semiconductor body exhibiting a respective stripe configuration, wherein at least some of the first trenches are control trenches housing a respective control trench electrode for controlling the load current in first semiconductor channel structures formed in the respective adjacent mesa portion; and
at the first side and in the active region, forming a deep cross trench extending into the semiconductor body along the vertical direction below bottoms of the first trenches and traversing a region corresponding to lower vertical projections of portions of the mesas,
wherein:
the deep cross trench includes a deep cross trench electrode and a deep cross trench insulator electrically insulating the deep cross trench electrode from the semiconductor body;
each of the control trenches includes a control trench insulator electrically insulating the control trench electrode from the semiconductor body; and
the thickness of the deep cross trench insulator amounts to at least 150% of an average thickness of the control trench insulators.

36. A method of forming a power semiconductor device, the method comprising:
forming a semiconductor body coupled to a first load terminal at a first side and to a second load terminal at a second side that is opposite to the first side with respect to a vertical direction, wherein the semiconductor body comprises an active region configured to conduct a load current between the first load terminal and the second load terminal;
at the first side and in the active region, forming a plurality of first trenches extending in the semiconductor body along the vertical direction, wherein the first trenches are arranged adjacent to each other along a first lateral direction and extend along a second lateral direction so as to exhibit a respective stripe configuration and thereby laterally confining mesas of the semiconductor body, wherein at least some of the first trenches are control trenches housing a respective control trench electrode for controlling the load current in first semiconductor channel structures formed in the respective adjacent mesa portion;
at the first side and in the active region, forming a deep cross trench extending into the semiconductor body along the vertical direction below bottoms of the first trenches and traversing a region corresponding to lower vertical projections of portions of the mesas, wherein at least an upmost portion of the deep cross trench is made of an insulating material, the upmost portion vertically overlapping with at least an average upmost quarter of the first trenches.
